(19) United States
(12) Patent Application Publication
(10) Pub. No.: US 2019/0373732 A1
(43) Pub. Date: Dec. 5, 2019

(54) PRINTED WIRING BOARD

(71) Applicant: IBIDEN CO., LTD., Ogaki (JP)

(72) Inventor: Hirotaka TANIGUCHI, Ogaki (JP)

(73) Assignee: IBIDEN CO., LTD., Ogaki (JP)

(21) Appl. No.: 16/426,005

(22) Filed: May 30, 2019

(30) Foreign Application Priority Data
May 30, 2018 (JP) 2018-103722

(51) Int. Cl. H05K 1/18; H05K 1/11; H05K 1/02

(52) U.S. Cl. CPC H05K 1/186; H05K 2201/10219; H05K 1/0206; H05K 1/115

(57) ABSTRACT

A printed wiring board includes a core substrate including core material and having opening through the core material, first electronic components in the opening each including a first electrode, second electronic components in the opening each including a third electrode, a first build-up layer formed on surface of the substrate and including a first insulating layer, a first conductor layer on the first insulating layer, first via conductors through the first insulating layer and connecting to the first conductor layer, and a third resin insulating layer on the first insulating layer. The first conductor layer includes first conductor circuit formed directly over the opening, and on-core-material first conductor circuit directly over the core material. Groups of the first via conductors connect the first electrodes to the first conductor circuit and the third electrodes to the first conductor circuit. Each first via conductor in the groups has a recessed top portion.

### CROSS-REFERENCE TO RELATED APPLICATIONS

The present application is based upon and claims the benefit of priority to Japanese Patent Application No. 2018-103722, filed May 30, 2018, the entire contents of which are incorporated herein by reference.

### BACKGROUND OF THE INVENTION

### Field of the Invention

The present invention relates to a printed wiring board in which first electronic components and second electronic components are accommodated in an opening.

### Description of Background Art

Japanese Patent Laid-Open Publication No. 2012-39050 describes a metal substrate in which Peltier elements are embedded. The entire contents of this publication are incorporated herein by reference.

### SUMMARY OF THE INVENTION

According to one aspect of the present invention, a printed wiring board includes a core substrate including a core material and having an opening such that the opening is penetrating through the core material, multiple first electronic components accommodated in the opening of the core substrate and each including a first main body, a first electrode on one side of the first main body, and a second electrode on the opposite side of the first main body, multiple second electronic components accommodated in the opening of the core substrate and each including a second main body, a third electrode on one side of the second main body, and a fourth electrode on the opposite side of the second main body, a first build-up layer formed on a surface of the core substrate and including a first resin insulating layer covering the opening of the core substrate, a first conductor layer formed on the first resin insulating layer, multiple first via conductors penetrating through the first resin insulating layer and connecting to the first conductor layer, and a third resin insulating layer formed on the first resin insulating layer such that the third resin insulating layer is formed over the first conductor layer and the first via conductors. The first build-up layer is formed such that the first conductor layer includes a first conductor circuit formed directly over the opening of the core substrate, and an on-core-material first conductor circuit formed directly over the core material, that the first via conductors include a group of the first via conductors that connects the first conductor layer to a conductor layer formed on the surface of the core substrate, a group of the first via conductors that connects the first electrodes of the first electronic components to the first conductor circuit, and a group of the first via conductors that connects the third electrodes of the second electronic components to the first conductor circuit, and that each of the first via conductors in the groups connected to the first and third electrodes has a recessed top portion.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1A is a cross-sectional view of a printed wiring board according to a first embodiment of the present invention;

FIGS. 1B and 1C are cross-sectional views of electronic components;

FIGS. 1D and 1E are cross-sectional views of via conductors;

FIGS. 2A and 2B are plan views illustrating wirings connected to electronic components;

FIGS. 3A-3D are manufacturing process diagrams of the printed wiring board of the first embodiment;

FIGS. 4A-4C are manufacturing process diagrams of the printed wiring board of the first embodiment;

FIGS. 5A and 5B are manufacturing process diagrams of the printed wiring board of the first embodiment;

FIG. 6A is a cross-sectional view of a printed wiring board according to a second embodiment of the present invention;

FIG. 6B is a schematic diagram illustrating a part of for-built-in-component wirings;

FIG. 6C illustrates positions of electronic components arranged in one row;

FIG. 6D illustrates positions of electronic components arranged in one column;

FIGS. 7A-7C illustrate a method for accommodating electronic components of the second embodiment;

FIGS. 8A-8J illustrate cross sections and recess amounts of first via conductors and second via conductors; and

FIGS. 9A-9C illustrate a method for accommodating electronic components of the first embodiment and positions of the electronic components.

### DETAILED DESCRIPTION OF THE EMBODIMENTS

Embodiments will now be described with reference to the accompanying drawings, wherein like reference numerals designate corresponding or identical elements throughout the various drawings.

### First Embodiment

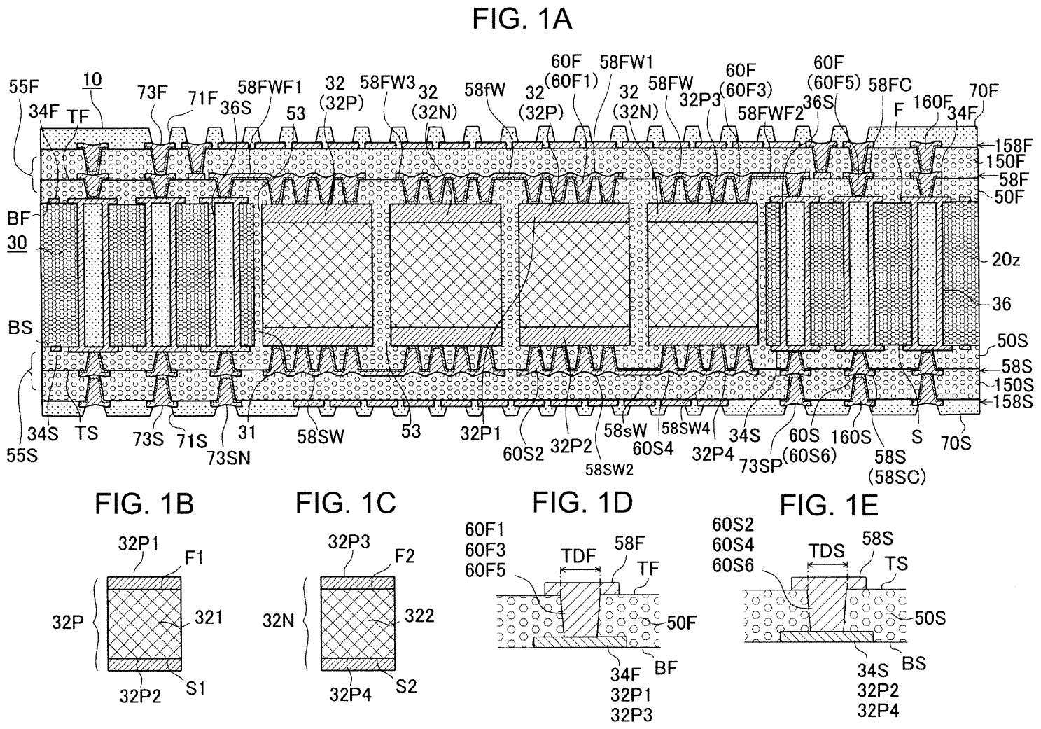

FIG. 1A is a cross-sectional view of a printed wiring board 10 of a first embodiment. The printed wiring board 10 has a core substrate 30 having a fifth surface (F) and a sixth surface (S) on an opposite side with respect to the fifth surface (F), a first build-up layer (55F) formed on the fifth surface (F) of the core substrate 30, and a second build-up layer (55S) formed on the sixth surface (S) of the core substrate 30.

The core substrate 30 has a core material (insulating substrate) (20z) having the fifth surface (F) and the sixth surface (S) on an opposite side with respect to the fifth surface (F), a fifth conductor layer (34F) formed on the fifth surface of the core material (20z), a sixth conductor layer (34S) formed on the sixth surface (S) of the core material (20z), and through-hole conductors 36 connecting the fifth conductor layer (34F) and the sixth conductor layer (34S) to each other. The core substrate 30 has an opening 31 that extends from the fifth surface (F) to the sixth surface (S). Multiple first electronic components (32P) and multiple second electronic components (32N) are accommodated in the opening 31. Spaces between the first electronic components (32P) and the second electronic components (32N) are filled with a resin 53. Spaces between the first electronic components (32P) and the core substrate 30 are filled with the resin 53. Spaces between the second electronic components (32N) and the core substrate 30 are filled with the resin 53. The first electronic components (32P) and the second electronic components (32N) are fixed to the core substrate 30 by the resin 53.

FIG. 1B illustrates one of the first electronic components (32P).

Each of the first electronic components (32P) has electrodes (32P1, 32P2) at two ends thereof. The first electronic components (32P) are each formed of a first main body 321 having a first surface (F1) and a second surface (S1) on an opposite side with respect to the first surface (F1), the first electrode (32P1) on the first surface (F1), and the second electrode (32P2) on the second surface (S1). The first main body 321 is sandwiched between the first electrode (32P1) and the second electrode (32P2). An example of the first main body 321 is a P-type semiconductor element or light emitting element.

The first electrode (32P1) faces the fifth surface (F) of the core substrate 30, and the second electrode (32P2) faces the sixth surface (S) of the core substrate 30. The P-type semiconductor element is preferably a P-type thermoelectric element. The first electronic components (32P) are embedded in the opening 31 such that the first electrodes (32P1) face the fifth surface (F).

FIG. 1C illustrates one of the second electronic components (32N).

Each of the second electronic components (32N) has electrodes (32P3, 32P4) at two ends thereof. The second electronic components (32N) are each formed of a second main body 322 having a third surface (F2) and a fourth surface (S2) on an opposite side with respect to the third surface (F2), the third electrode (32P3) on the third surface (F2), and the fourth electrode (32P4) on the fourth surface (S2). The second main body 322 is sandwiched between the third electrode (32P3) and the fourth electrode (32P4). An example of the second main body 322 is an N-type semiconductor element or light receiving element.

The third electrode (32P3) faces the fifth surface (F) of the core substrate 30, and the fourth electrode (32P4) faces the sixth surface (S) of the core substrate 30. The N-type semiconductor element is preferably an N-type thermoelectric element. The second electronic components (32N) are embedded in the opening 31 such that the third electrodes (32P3) face the fifth surface (F).

The first build-up layer (55F) has a first resin insulating layer (50F) formed on the fifth surface (F) of the core substrate 30 and on the fifth conductor layer (34F), a first conductor layer (58F) formed on the first resin insulating layer (50F), a third resin insulating layer (150F) formed on the first conductor layer (58F) and on the first resin insulating layer (50F), and a third conductor layer (158F) formed on the third resin insulating layer (150F). The first resin insulating layer (50F) covers the opening 31. The resin 53 and the first resin insulating layer (50F) are integrally formed. Spaces between the first electronic components (32P) and a side wall of the core substrate 30 exposed from the opening 31 are filled with a resin originating from the first resin insulating layer (50F). Spaces between the second electronic components (32N) and the side wall of the core substrate 30 exposed from the opening 31 are filled with the resin originating from the first resin insulating layer (50F). Spaces between the first electronic components (32P) and the second electronic components (32N) are filled with the resin originating from the first resin insulating layer (50F). A component originating from the first resin insulating layer (50F) forms the resin 53. The resin 53 can contain a resin and inorganic particles originating from the first resin insulating layer (50F).

The first conductor layer (58F) has a first conductor circuit (58FW) formed directly over the opening 31, and an on-core-material first conductor circuit (58FC) formed directly over the core material (20z). Adjacent first electronic components (32P) and second electronic components (32N) are connected to each other by the first conductor circuit (58FW).

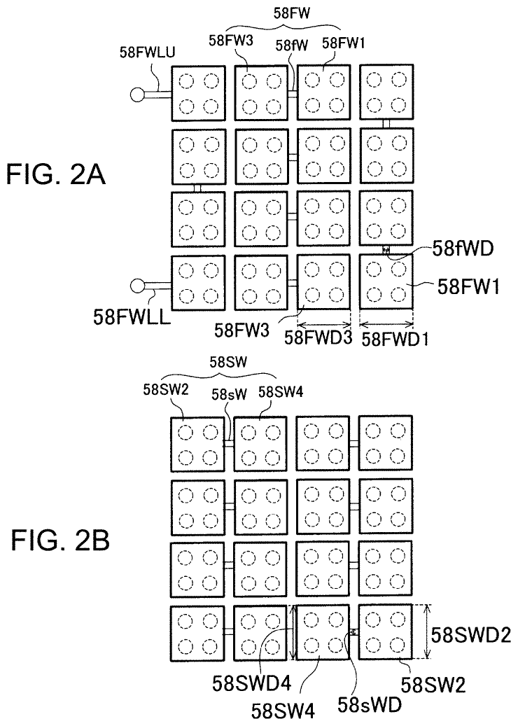

FIG. 2A is a plan view illustrating the first conductor circuit (58FW). The first conductor circuit (58FW) includes on-first-electrode first conductor circuits (58FW1) respectively covering the first electrodes (32P1), on-third-electrode first conductor circuits (58FW3) respectively covering the third electrodes (32P3), and first wirings (58fW) each connecting one of the on-first-electrode first conductor circuits (58FW1) to one of the on-third-electrode first conductor circuits (58FW3). The on-first-electrode first conductor circuits (58FW1) are respectively positioned on the first electrodes (32P1), and a size of each of the on-first-electrode first conductor circuits (58FW1) is larger than a size of each of the first electrodes (32P1). The on-third-electrode first conductor circuits (58FW3) are respectively positioned on the third electrodes (32P3), and a size of each of the on-third-electrode first conductor circuits (58FW3) is larger than a size of each of the third electrodes (32P3). A width (58fWD) of each of the first wirings (58fW) is equal to a width (58FWD1) of each of the on-first-electrode first conductor circuits (58FW1). Or, the width (58fWD) of each of the first wirings (58fW) is smaller than the width (58FWD1) of each of the on-first-electrode first conductor circuits (58FW1). The width (58fWD) of each of the first wirings (58fW) is equal to a width (58FWD3) of each of the on-third-electrode first conductor circuits (58FW3). Or, the width (58fWD) of each of the first wirings (58fW) is smaller than the width (58FWD3) of each of the on-third-electrode first conductor circuits (58FW3).

Dotted lines in the on-first-electrode first conductor circuits (58FW1) respectively indicate outer peripheries of top parts of for-first-electrode first via conductors (60F1). The on-first-electrode first conductor circuits (58FW1) are connected to the first electrodes (32P1) by the multiple for-first-electrode first via conductors (60F1).

Dotted lines in the on-third-electrode first conductor circuits (58FW3) respectively indicate outer peripheries of top parts of for-third-electrode first via conductors (60F3). The on-third-electrode first conductor circuits (58FW3) are connected to the third electrodes (32P3) by the multiple for-third-electrode first via conductors (60F3).

One on-first-electrode first conductor circuit (58FW1) is formed on one first electrode (32P1). One on-third-electrode first conductor circuit (58FW3) is formed on one third electrode (32P3).

The first build-up layer (55F) further has first via conductors (60F) penetrating the first resin insulating layer (50F) and third via conductors (160F) penetrating the third resin insulating layer (150F). The first via conductors (60F) include via conductors (for-fifth-conductor-layer first via conductors) (60F5) that connect the fifth conductor layer (34F) to the on-core-material first conductor circuit (58FC), the via conductors (the for-first-electrode first via conductors) (60F1) that connect the first electrodes (32P1) to the on-first-electrode first conductor circuits (58FW1), and the via conductors (the for-third-electrode first via conductors) (60F3) that connect the third electrodes (32P3) to the on-third-electrode first conductor circuits (58FW3). The number of the for-first-electrode first via conductors (60F1) that connect one of the first electrodes (32P1) to one of the on-first-electrode first conductor circuits (58FW1) is 2 or more. For example, the number of the for-first-electrode first via conductors (60F1) reaching one of the first electrodes (32P1) is 20 or more. A heat dissipation effect can be increased. Connection reliability can be increased even when the electronic components 32 expand or contract. The number of the for-third-electrode first via conductors (60F3) that connect one of the third electrodes (32P3) to one of the on-third-electrode first conductor circuits (58FW3) is 2 or more. For example, the number of the for-third-electrode first via conductors (60F3) reaching one of the third electrodes (32P3) is 20 or more. The heat dissipation effect can be increased. The connection reliability can be increased even when the electronic components 32 expand or contract.

The first resin insulating layer (50F) has a bottom surface (BF) opposing the fifth surface (F) and a top surface (TF) on an opposite side with respect to the bottom surface (BF). Then, the for-fifth-conductor-layer first via conductors (60F5), the for-first-electrode first via conductors (60F1) and the for-third-electrode first via conductors (60F3) each have a top diameter (TDF) at a position of the top surface (TF). The top diameter (TDF) of each of the for-fifth-conductor-layer first via conductors (60F5), the top diameter (TDF) of each of the for-first-electrode first via conductors (60F1), and the top diameter (TDF) of each of the for-third-electrode first via conductors (60F3) are substantially equal to each other. The top diameter (TDF) is illustrated in FIG. 1D.

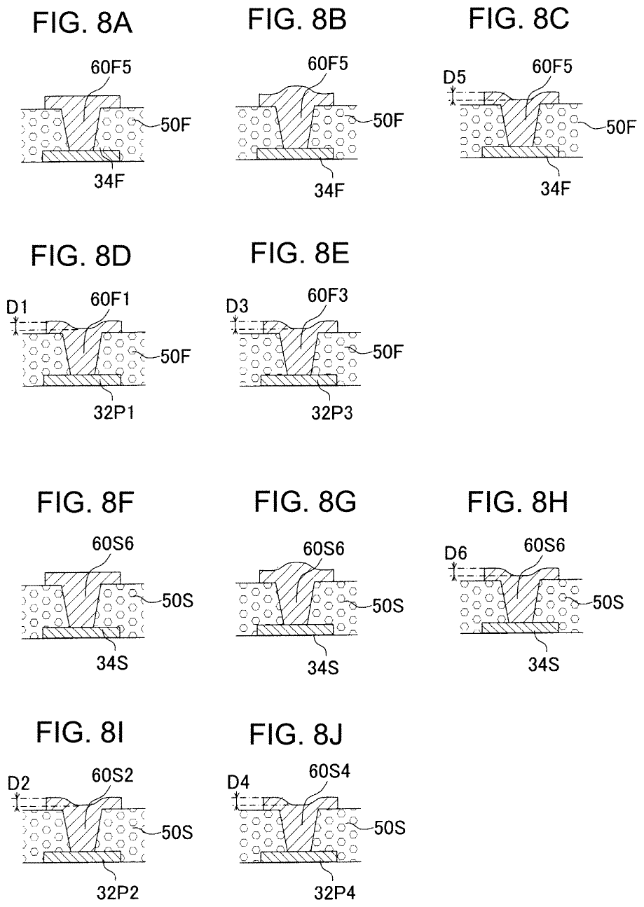

The top part of each of the for-fifth-conductor-layer first via conductors (60F5) is flat, or convex, or recessed. A top part of a for-fifth-conductor-layer first via conductor (60F5) illustrated in FIG. 8A is flat. A top part of a for-fifth-conductor-layer first via conductor (60F5) illustrated in FIG. 8B is convex. A top part of a for-fifth-conductor-layer first via conductor (60F5) illustrated in FIG. 8C is recessed. When a top part of a for-fifth-conductor-layer first via conductor (60F5) is recessed, the top part has a recess amount (D5). The recess amount (D5) is illustrated in FIG. 8C.

The top part of each of the for-first-electrode first via conductors (60F1) and the for-third-electrode first via conductors (60F3) has a recess. A top part of a for-first-electrode first via conductor (60F1) illustrated in FIG. 8D is recessed. A top part of a for-third-electrode first via conductor (60F3) illustrated in FIG. 8D is recessed. The top part of each of the for-first-electrode first via conductors (60F1) has a recess amount (D1). The top part of each of the for-third-electrode first via conductors (60F3) has a recess amount (D3). The recess amount (D1) is illustrated in FIG. 8D. The recess amount (D3) is illustrated in FIG. 8E.

The recess amount (D1) is larger than the recess amount (D5). The recess amount (D3) is larger than the recess amount (D5). When there is variation in the recess amount (D1), the recess amount (D1) has a minimum recess amount (D1min). When there is variation in the recess amount (D3), the recess amount (D3) has a minimum recess amount (D3min). When there is variation in the recess amount (D5), the recess amount (D5) has a maximum recess amount (D5max). The recess amount (D1min) is larger than the recess amount (D5max). The recess amount (D3min) is larger than the recess amount (D5max). The recess amount (D1) and the recess amount (D3) are each larger than 5 μm and smaller than 15 μm. The recess amount (D5) is larger than 3 μm and smaller than 10 μm.

The third resin insulating layer (150F) covers the top parts of the for-fifth-conductor-layer first via conductors (60F5), the top parts of the for-first-electrode first via conductors (60F1), and the top parts of the for-third-electrode first via conductors (60F3). The third resin insulating layer (150F) fills the recesses formed in the top parts of the for-first-electrode first via conductors (60F1). The third resin insulating layer (150F) fills the recesses formed in the top parts of the for-third-electrode first via conductors (60F3).

The second build-up layer (55S) has a second resin insulating layer (50S) formed on the sixth surface (S) of the core substrate 30 and on the sixth conductor layer (34S), a second conductor layer (58S) formed on the second resin insulating layer (50S), a fourth resin insulating layer (150S) formed on the second conductor layer (58S) and on the second resin insulating layer (50S), and a fourth conductor layer (158S) formed on the fourth resin insulating layer (150S).

The second conductor layer (58S) has a second conductor circuit (58SW) formed directly over the opening 31, and an on-core-material second conductor circuit (58SC) formed directly over the core material (20z).

Adjacent first electronic components (32P) and second electronic components (32N) are connected to each other by the second conductor circuit (58SW).

FIG. 2B is a plan view illustrating the second conductor circuit (58SW). The second conductor circuit (58SW) includes on-second-electrode second conductor circuits (58SW2) respectively covering the second electrodes (32P2), on-fourth-electrode second conductor circuits (58SW4) respectively covering the fourth electrodes (32P4), and second wirings (58sW) each connecting an on-second-electrode second conductor circuit (58SW2) to an on-fourth-electrode second conductor circuit (58SW4). The on-second-electrode second conductor circuits (58SW2) are respectively positioned on the second electrode (32P2), and a size of each of the on-second-electrode second conductor circuits (58SW2) is larger than a size of each of the second electrodes (32P2). The on-fourth-electrode second conductor circuits (58SW4) are respectively positioned on the fourth electrode (32P4), and a size of each of the on-fourth-electrode second conductor circuits (58SW4) is larger than a size of each of the fourth electrodes (32P4). A width (58sWD) of each of the second wirings (58sW) is equal to a width (58SWD2) of each of the on-second-electrode second conductor circuits (58SW2). Or, the width (58sWD) of each of the second wirings (58sW) is smaller than the width (58SWD2) of each of the on-second-electrode second conductor circuits (58SW2). The width (58sWD) of each of the second wirings (58sW) is equal to a width (58SWD4) of each of the on-fourth-electrode second conductor circuits (58SW4). Or, the width (58sWD) of each of the second wirings (58sW) is smaller than the width (58SWD4) of each of the on-fourth-electrode second conductor circuits (58SW4).

Dotted lines in the on-second-electrode second conductor circuits (58SW2) respectively indicate outer peripheries of top parts of for-second-electrode second via conductors (60S2). The on-second-electrode second conductor circuits (58SW2) are connected to the second electrodes (32P2) by the multiple for-second-electrode second via conductors (60S2).

Dotted lines in the on-fourth-electrode second conductor circuit (58SW4) respectively indicate outer peripheries of top parts of for-fourth-electrode second via conductors (60S4). The on-fourth-electrode second conductor circuits (58SW4) are connected to the fourth electrodes (32P4) by the multiple for-fourth-electrode second via conductors (60S4).

One on-second-electrode second conductor circuit (58SW2) is formed on one second electrode (32P2). One on-fourth-electrode second conductor circuit (58SW4) is formed on one fourth electrode (32P4).

The second build-up layer (55S) further has second via conductors (60S) penetrating the second resin insulating layer (50S) and fourth via conductors (160S) penetrating the fourth resin insulating layer (150S). The second via conductors (60S) include via conductors (for-sixth-conductor-layer second via conductors) (60S6) that connect the sixth conductor layer (34S) to the on-core-material second conductor circuit (58SC), the via conductors (the for-second-electrode second via conductors) (60S2) that connect the second electrodes (32P2) to the on-second-electrode second conductor circuits (58SW2), and the via conductors (the for-fourth-electrode second via conductors) (60S4) that connect the fourth electrodes (32P4) to the on-fourth-electrode second conductor circuits (58SW4). The number of the for-second-electrode second via conductors (60S2) that connect one second electrode (32P2) to one on-second-electrode second conductor circuit (58SW2) is 2 or more. For example, the number of the for-second-electrode second via conductors (60S2) reaching one second electrode (32P2) is 20 or more. The heat dissipation effect can be increased. The connection reliability can be increased even when the electronic components 32 expand or contract. The number of the for-fourth-electrode second via conductors (60S4) that connect one fourth electrode (32P4) to one on-fourth-electrode second conductor circuit (58SW4) is 2 or more. For example, the number of the for-fourth-electrode second via conductors (60S4) reaching one fourth electrode (32P4) is 20 or more. The heat dissipation effect can be increased. The connection reliability can be increased even when the electronic components 32 expand or contract.

The second resin insulating layer (50S) has a bottom surface (BS) opposing the sixth surface (S) and a top surface (TS) on an opposite side with respect to the bottom surface (BS). Then, the for-sixth-conductor-layer second via conductors (60S6), the for-second-electrode second via conductors (60S2) and the for-fourth-electrode second via conductors (60S4) each have a top diameter (TDS) at a position of the top surface (TS). The top diameter (TDS) of each of the for-sixth-conductor-layer second via conductors (60S6), the top diameter (TDS) of each of the for-second-electrode second via conductors (60S2) and the top diameter (TDS) of each of the for-fourth-electrode second via conductors (60S4) are substantially equal to each other. The top diameter (TDS) is illustrated in FIG. 1E.

The top part of each of the for-sixth-conductor-layer second via conductors (60S6) is flat, or convex, or recessed. A top part of a for-sixth-conductor-layer second via conductor (60S6) illustrated in FIG. 8F is flat. A top part of a for-sixth-conductor-layer second via conductor (60S6) illustrated in FIG. 8G is convex. A top part of a for-sixth-conductor-layer second via conductor (60S6) illustrated in FIG. 8H is recessed. When a top part of a for-sixth-conductor-layer second via conductor (60S6) is recessed, the top part has a recess amount (D6). The recess amount (D6) is illustrated in FIG. 8H.

The top part of each of the for-second-electrode second via conductors (60S2) and the for-fourth-electrode second via conductors (60S4) has a recess. A top part of a for-second-electrode second via conductor (60S2) illustrated in FIG. 8I is recessed. A top part of a for-fourth-electrode second via conductor (60S4) illustrated in FIG. 8J is recessed. The top part of each of the for-second-electrode second via conductors (60S2) has a recess amount (D2). The top part of each of the for-fourth-electrode second via conductors (60S4) has a recess amount (D4). The recess amount (D2) is illustrated in FIG. 81. The recess amount (D4) is illustrated in FIG. 8J.

The recess amount (D2) is larger than the recess amount (D6). The recess amount (D4) is larger than the recess amount (D6). When there is variation in the recess amount (D2), the recess amount (D2) has a minimum recess amount (D2min). When there is variation in the recess amount (D4), the recess amount (D4) has a minimum recess amount (D4min). When there is variation in the recess amount (D6), the recess amount (D6) has a maximum recess amount (D6max). The recess amount (D2min) is larger than the recess amount (D6max). The recess amount (D4min) is larger than the recess amount (D6max). The recess amount (D2) and the recess amount (D4) are each larger than 5 μm and smaller than 15 μm. The recess amount (D6) is larger than 3 μm and smaller than 10 μm.

The recess amount (D2) and the recess amount (D4) are larger than the recess amount (D1) and the recess amount (D3). The recess amount (D2min) and the recess amount (D4min) are larger than the recess amount (D1min) and the recess amount (D3min).

The fourth resin insulating layer (150S) covers the top parts of the for-sixth-conductor-layer second via conductors (60S6), the top parts of the for-second-electrode second via conductors (60S2), and the top parts of the for-fourth-electrode second via conductors (60S4). The fourth resin insulating layer (150S) fills the recesses formed in the top parts of the for-second-electrode second via conductors (60S2). The fourth resin insulating layer (150S) fills the recesses formed in the top parts of the for-fourth-electrode second via conductors (60S4).

A second solder resist layer (70S) having openings (71S) can be formed on the fourth conductor layer (158S) and the fourth resin insulating layer (150S). The fourth conductor layer (158S) exposed from the openings (71S) form second pads (73S) for connecting to a wiring board such as a motherboard.

A first solder resist layer (70F) having openings (71F) can be formed on the third resin insulating layer (150F) and the third conductor layer (158F). The third conductor layer (158F) exposed from the openings (71F) forms first pads (73F) for mounting an electronic component. Examples of the electronic component to be mounted on the first pads (73F) include an LED and a power semiconductor, for which a heat generation amount is large when driven.

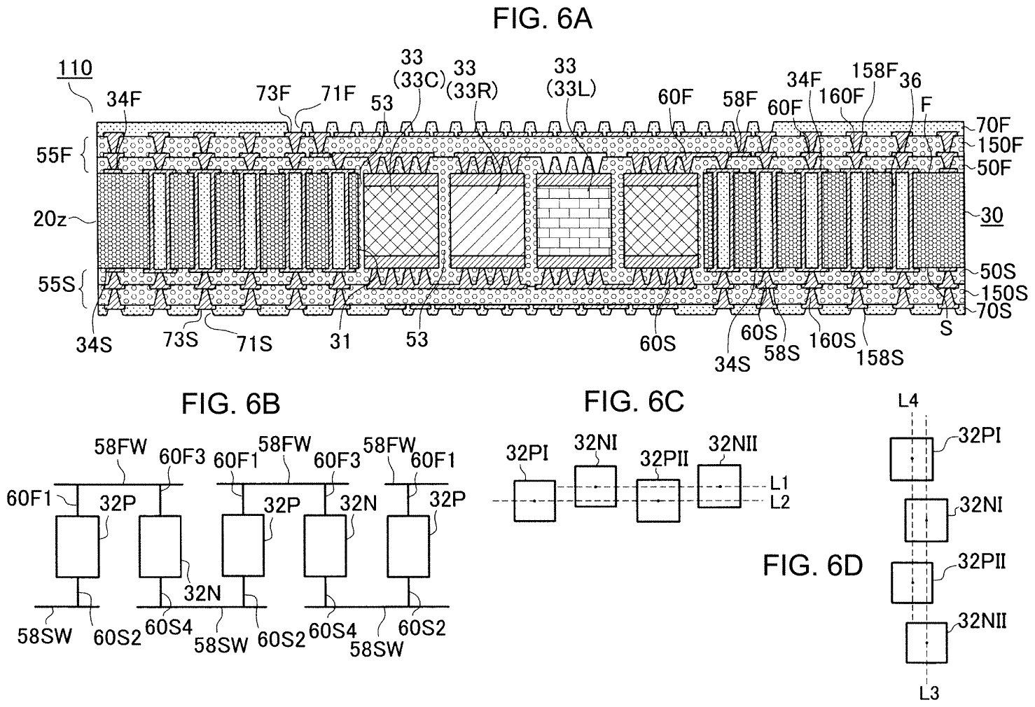

A method for connection between the first electronic components (32P), the second electronic components (32N), the first conductor circuit (58FW), the for-first-electrode first via conductors (60F1), the for-third-electrode first via conductors (60F3), the second conductor circuit (58SW), the for-second-electrode second via conductors (60S2) and the for-fourth-electrode second via conductors (60S4) is schematically illustrated in FIGS. 6B, 2A, and 2B. FIG. 6B is a cross-sectional view. As illustrated in these drawings, the first electronic components (32P) and the second electronic components (32N) are connected in series via the first conductor circuit (58FW), the for-first-electrode first via conductors (60F1), the for-third-electrode first via conductors (60F3), the second conductor circuit (58SW), the for-second-electrode second via conductors (60S2) and the for-fourth-electrode second via conductors (60S4). The first electronic components (32P) and the second electronic components (32N) are alternately connected. The first electronic components (32P) and the second electronic components (32N) are alternately arranged and connected in series. Connections between the first electronic components (32P) and the second electronic components (32N) via the first conductor circuit (58FW) and connections between the first electronic components (32P) and the second electronic components (32N) via the second conductor circuit (58SW) are alternately repeated.

As illustrated in FIG. 1A, the second pads (73S) include second pads (plus pads) (73SP) having a plus electric potential and second pads (minus pads) (73SN) having a minus electric potential. And, the multiple first electronic components (32P) and the multiple second electronic components (32N) are arranged between the plus pads (73SP) and the minus pads (73SN). Wirings (for-built-in-component wirings) from the plus pads (73SP) to the minus pads (73SN) via the first electronic components (32P) and the second electronic components (32N) are independent in the printed wiring board 10. The for-built-in-component wirings include the first conductor circuit (58FW), the for-first-electrode first via conductors (60F1), the for-third-electrode first via conductors (60F3), the second conductor circuit (58SW), the for-second-electrode second via conductors (60S2), and the for-fourth-electrode second via conductors (60S4). The for-built-in-component wirings are not connected to conductor circuits in the printed wiring board other than the for-built-in-component wirings. Data transmitted in the printed wiring board 10 is unlikely to deteriorate. Through-hole conductors (36S) surrounding the opening 31 are included in the for-built-in-component wirings. For example, the number of the through-hole conductors (36S) included in the for-built-in-component wirings is 2. A first conductor circuit (58FWLU) at upper left of FIG. 2B extends from a position above the opening 31 to a position above the core material (20z) and connects to a through-hole conductor (36S). A first conductor circuit (58FWLL) at lower left of FIG. 2A extends from a position above the opening 31 to a position above the core material (20z) and connects to a through-hole conductor (36S).

Second pads having an electric potential lower than that of the plus pads are included in the minus pads.

The first electronic components (32P) and the second electronic components (32N) are connected to the first conductor circuit (58FW) via the first via conductors (60F). Therefore, even when the first electronic components (32P) and the second electronic components (32N) are embedded in the core substrate, heat can be transmitted to the first electronic components (32P) and the second electronic components (32N) via the first conductor circuit (58FW). Heat can be efficiently transmitted to the first electronic components (32P) and the second electronic components (32N). Temperature rise of an electronic component mounted on the printed wiring board can be suppressed. For example, heat is generated from an electronic component mounted on the first pads (73F). In a cross-sectional direction, the core substrate 30 is positioned substantially at a center of the printed wiring board. The cross-sectional direction is perpendicular to the fifth surface (F).

The first electronic components (32P) and the second electronic components (32N) are connected to the second conductor circuit (58SW) via the second via conductors (60S). Therefore, even when the first electronic components (32P) and the second electronic components (32N) are embedded in the core substrate, heat can be transmitted to outside via the second conductor circuit (58SW). Heat can be efficiently transmitted to the outside. For example, heat can be transmitted to a motherboard.

Temperature rise of an electronic component mounted on the printed wiring board can be suppressed.

The core material (20z) is formed of a resin such as an epoxy resin and a reinforcing material such as a glass cloth. The core material (20z) may further contain inorganic particles such as silica particles. The first resin insulating layer (50F), the second resin insulating layer (50S), the third resin insulating layer (150F), and the fourth resin insulating layer (150S) are each formed of a resin such as an epoxy resin and inorganic particles such as silica particles. The first resin insulating layer (50F), the second resin insulating layer (50S), the third resin insulating layer (150F), and the fourth resin insulating layer (150S) may each further contain a reinforcing material such as glass cloth.

In the printed wiring board 10 of the first embodiment, heat from an electronic component mounted on the first pads (73F) can be transmitted to a wiring board via the second pads (73S) by applying an electric current to the first electronic components (32P) and the second electronic components (32N).

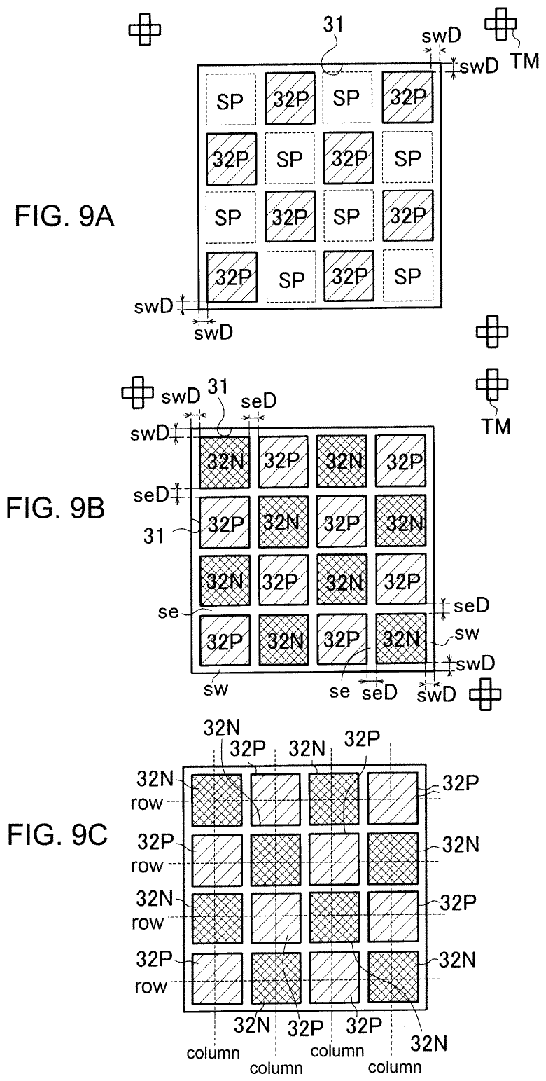

FIG. 9C illustrates an arrangement of the first electronic components (32P) and the second electronic components (32N) accommodated in the opening 31 of the core substrate 30. The first electronic components (32P) and the second electronic components (32N) are alternately arranged. Each of the second electronic components (32N) is positioned adjacent to one of the first electronic components (32P). As illustrated in FIG. 9C, on the drawing, an electronic component positioned above a first electronic component (32P) is a second electronic component (32N), an electronic component positioned below a first electronic component (32P) is a second electronic component (32N), an electronic component positioned on a right side of a first electronic component (32P) is a second electronic component (32N), and an electronic component positioned on a left side of a first electronic component (32P) is a second electronic component (32N). An electronic component positioned above a second electronic component (32N) is a first electronic component (32P), an electronic component positioned below a second electronic component (32N) is a first electronic component (32P), an electronic component positioned on a right side of a second electronic component (32N) is a first electronic component (32P), and an electronic component positioned on a left side of a second electronic component (32N) is a first electronic component (32P).

The number of the first electronic components (32P) and the number of the second electronic components (32N) accommodated in the one opening 31 are equal to each other.

Multiple kinds of electronic components are embedded in the one opening 31. Examples of the electronic components are the first electronic components (32P) and the second electronic components (32N). Further, the number of the electronic components of each kind is 2 or more. The core substrate 30 is not present between adjacent electronic components. The core material (20z) is not present between adjacent electronic components. Therefore, a size of the opening 31 for accommodating the electronic components can be reduced. A size of the printed wiring board 10 can be reduced. The number of the first electronic components (32P) is 10 or more, and the number of the second electronic components (32N) is 10 or more.

For example, the first electronic components (32P) and the second electronic components (32N) each have a cubical shape. An example of a length of each side is 1 mm.

As illustrated in FIG. 9B, a space (se) exists between a first electronic component (32P) and a second electronic component (32N) which are adjacent to each other. The spaces (se) each have a width (seD) of 10 μm or more and 50 μm or less. Due to the existence of the spaces (se), interference between the first electronic components (32P) and the second electronic components (32N) can be suppressed.

As illustrated in FIG. 9B, a space (sw) exists between the core substrate 30 and a first electronic component (32P). The space (sw) exists between the core substrate 30 and a second electronic component (32N). The space (sw) has a width (swD) of 15 μm or more and 50 μm or less. Due to the existence of the space (sw), interference between the first electronic components (32P) and the fifth conductor layer (34F) can be suppressed. Interference between the second electronic components (32N) and the fifth conductor layer (34F) can be suppressed. Interference between the first electronic components (32P) and the sixth conductor layer (34S) can be suppressed. Interference between the second electronic components (32N) and the sixth conductor layer (34S) can be suppressed.

According to the printed wiring board 10 of the first embodiment, the multiple electronic components (the first electronic component (32P) and the second electronic components (32N)) 32 are accommodated in the one opening 31. Even when a large number of electronic components are embedded in the printed wiring board 10, the size of the printed wiring board 10 can be reduced. Even when the multiple electronic components are embedded in the printed wiring board, the printed wiring board 10 having a small size and a high cooling effect can be provided.

The spaces (se) and the spaces (sw) are filled with the resin 53 originating from the first resin insulating layer (50F). Therefore, the resin 53 fanned in the opening 31 and the first resin insulating layer (50F) are integrally formed. An interface between the resin 53 and the first resin insulating layer (50F) is not formed. Therefore, even when the electronic components 32 in the opening 31 are subjected to repeated thermal expansion and thermal contraction, peeling does not occur between the resin 53 and the first resin insulating layer (50F). A highly reliable printed wiring board 10 can be provided. Since the sizes (seD, swD) of the spaces (se) and the spaces (sw) are in appropriate ranges, the resin 53 originating from the first resin insulating layer (50F) can enter into the spaces (se, sw). The spaces (se, sw) can be filled with the resin 53 originating from the first resin insulating layer (50F).

When the top part of each of the via conductors has a recess and the recess is filled with the resin insulating layer, a contact area between the resin insulating layer and the via conductors is increased. Therefore, the resin insulating layer is unlikely to peel off from the via conductors. When heat accumulated in the resin insulating layer is transmitted to the via conductors, the contact area between the resin insulating layer and the via conductors and a transmission speed are related to each other. Since the contact area is increased due to the recesses, heat is efficiently transmitted from the resin insulating layer to the via conductors. Heat is efficiently transmitted from the via conductors to the resin insulating layer.

When the top parts of all the for-first-electrode first via conductors (60F1) and all the for-third-electrode first via conductors (60F3) each have a recess, the resin insulating layer is unlikely to peel off from the via conductors. Heat is efficiently transmitted from the resin insulating layer to the via conductors.

When the top parts of all the for-second-electrode second via conductors (60S2) and all the for-fourth-electrode second via conductors (60S4) each have a recess, the resin insulating layer is unlikely to peel off from the via conductors. Heat is efficiently transmitted from the via conductors to the resin insulating layer.

Heat generated by an electronic component mounted on the printed wiring board 10 reaches the for-first-electrode first via conductors (60F1) and the for-third-electrode first via conductors (60F3) via the third resin insulating layer (150F). Then, the heat is transmitted to the first electronic components (32P) and the second electronic components (32N) via the for-first-electrode first via conductors (60F1) and the for-third-electrode first via conductors (60F3). After that, the heat reaches the fourth resin insulating layer (150S) via the for-second-electrode second via conductors (60S2) and the for-fourth-electrode second via conductors (60S4). Then, the heat reaches a motherboard via the second pads (73S). The heat is released to the outside.

The first wirings (58fW) connect to each other only electronic components of different kinds. The second wirings (58sW) connect to each other only electronic components of different kinds. Interference between electronic components of the same kind can be suppressed. For example, each of the electronic components can exert its maximum capacity. A heat dissipation effect can be increased.

### Manufacturing Method of First Embodiment

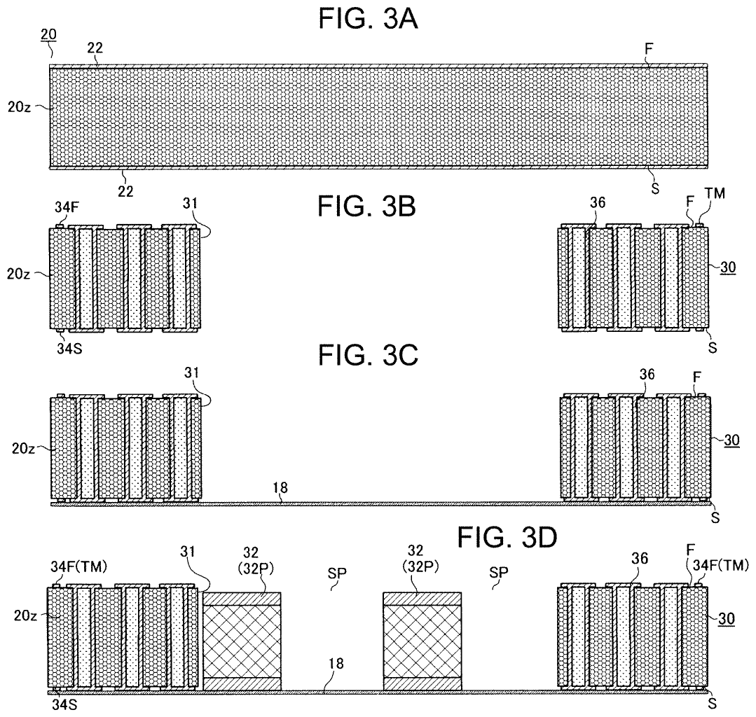

FIGS. 3A-5B illustrate a method for manufacturing the printed wiring board of the first embodiment.

A double-sided copper-clad laminated plate 20 is prepared (FIG. 3A). The double-sided copper-clad laminated plate 20 is formed of the core material (20z) having the fifth surface (F) and the sixth surface (S) on an opposite side with respect to the fifth surface (F) and a copper foil 22 laminated on both sides of the core material (20z).

Through holes for through-hole conductors are formed in the double-sided copper-clad laminated plate 20. The through-hole conductors 36 are formed in the through holes for through-hole conductors. After that, using a subtractive method, the fifth conductor layer (34F) is formed on the fifth surface (F) of the core material (20z). The sixth conductor layer (34S) is formed on the sixth surface (S) of the core material (20z). The fifth conductor layer (34F) and the sixth conductor layer (34S) are connected to each other by the through-hole conductors 36. A circuit substrate is completed. The fifth conductor layer (34F) has an alignment mark (TM). Using the alignment mark (TM) as a reference, the opening 31 penetrating the circuit substrate is formed at a center part of the circuit substrate. The core substrate 30 having the fifth surface (F) and the sixth surface (S) on an opposite side with respect to the fifth surface (F) is completed (FIG. 3B). The core substrate 30 has the fifth conductor layer (34F), the sixth conductor layer (34S), the through-hole conductors 36, and the opening 31. The fifth surface (F) of the core substrate 30 and the fifth surface (F) of the core material (20z) are the same surface, and the sixth surface (S) of the core substrate 30 and the sixth surface (S) of the core material (20z) are the same surface.

A tape 18 is pasted on the sixth surface (S) of the core substrate 30, and the opening 31 is closed (FIG. 3C). Using the alignment mark (TM) as a reference, first, the first electronic components (32P) are mounted one by one on the tape exposed from the opening 31. In this case, as illustrated in FIG. 9A, the first electronic components (32P) are mounted on the tape 18 such that the first electronic components (32P) and spaces (SP) for mounting the second electronic components (32N) are adjacent to each other (FIG. 3D). The first electronic components (32P) are arranged in rows and columns, and the first electronic components (32P) and the spaces (SP) are alternately arranged. The mounting of the first electronic components (32P) is completed. All the first electronic components (32P) accommodated in the one opening 31 are amounted on the tape 18.

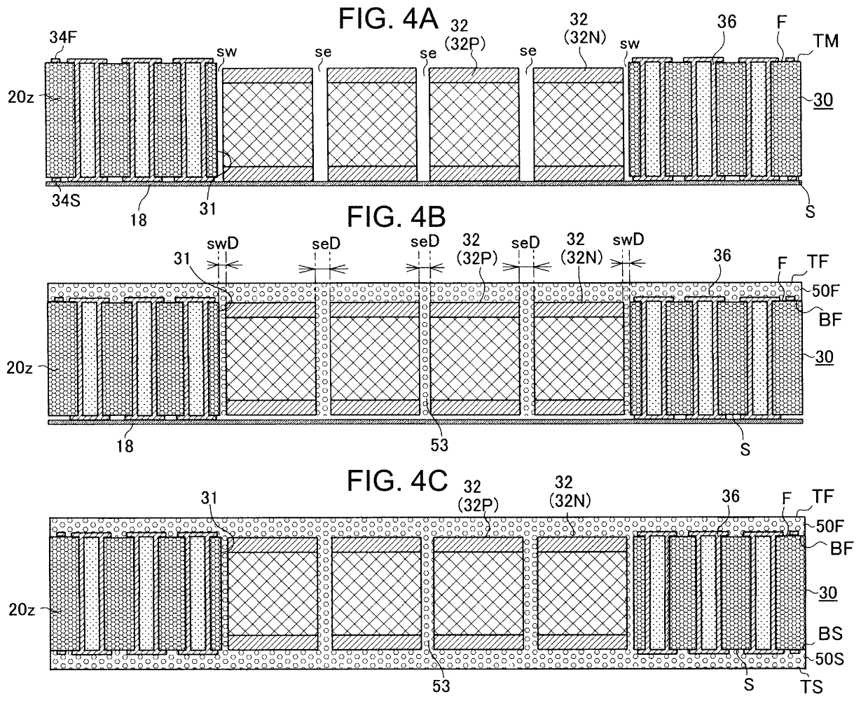

After that, using the alignment mark (TM) as a reference, the second electronic components (32N) are mounted one by one on the tape exposed from the opening 31 and the first electronic components (32P). In this case, as illustrated in FIG. 9B, the second electronic components (32N) are placed in the spaces (SP). The first electronic components (32P) and the second electronic components (32N) are adjacent to each other. The second electronic components (32N) are arranged in rows and columns, and the first electronic components (32P) and the second electronic components (32N) are alternately arranged (FIG. 4A). As illustrated in FIG. 9C, the first electronic components (32P) and the second electronic components (32N) are arranged at intersection points of rows and columns. The number of the rows and the number of the columns are the same. The number of the rows is 4 or more, and the number of the columns is 4 or more. In the method for manufacturing the printed wiring board of the first embodiment, first, all the first electronic components (32P) are accommodated in the opening 31. After that, all the second electronic components (32N) are accommodated in the opening 31. Therefore, the two kinds of electronic components (32P, 32N) can be accommodated at correct positions. The formation of the opening 31 and the mounting of the electronic components (32P, 32N) are performed using the same alignment mark (TM) as a reference. Therefore, positional accuracy between the opening 31 and the electronic components (32P, 32N) can be increased. Positional accuracy between the first electronic components (32P) and the second electronic components (32N) can be increased. The width (seD) of each of the spaces (se) can be set in a predetermined range (10 gm or more and 50 μm or less). The width (swD) of each of the spaces (sw) can be set in a predetermined range (15 μm or more and 50 μm or less).

A mounting order of the first electronic components (32P) and the second electronic components (32N) is arbitrary.

When the electronic components (32P, 32N) are mounted on the tape 18, an uncured film for resin insulating layer formation is laminated on the fifth surface (F) of the core substrate 30. In this case, the film for resin insulating layer formation covers the opening 31. After that, by hot pressing, the film for resin insulating layer formation is softened. The spaces (se) and the spaces (sw) are filled with a resin containing inorganic particles originating from the film for resin insulating layer formation (FIG. 4B). The film for resin insulating layer formation, the resin filled in the spaces (se), and the resin filled in the spaces (sw) are cured. The first resin insulating layer (50F) is formed on the core substrate 30 and the opening 31. The resin 53 filled in the spaces (se) and the spaces (sw) is formed. The first resin insulating layer (50F) and the resin 53 are integrally formed.

The first resin insulating layer (50F) has the bottom surface (BF) opposing the fifth surface (F) and the top surface (TF) on an opposite side with respect to the bottom surface (BF).

The tape 18 is removed from the core substrate 30. The second resin insulating layer (50S) is fanned on the sixth surface (S) of the core substrate 30 and the opening 31 (FIG. 4C).

The second resin insulating layer (50S) has the bottom surface (BS) opposing the sixth surface (S) and the top surface (TS) on an opposite side with respect to the bottom surface (BS).

The first conductor layer (58F) is formed on the first resin insulating layer (50F). At the same time, the first via conductors (60F) penetrating the first resin insulating layer (50F) are formed. The first conductor layer (58F) and the first via conductors (60F) are formed using a semi-additive method. Openings for the first via conductors penetrating the first resin insulating layer (50F) are formed. Then, by filling the openings, the first via conductors (60F) are formed. The openings for the first via conductors each have the top diameter (TDF) at the position of the top surface (TF) of the first resin insulating layer (50F).

The first conductor layer (58F) includes the on-first-electrode first conductor circuits (58FW1) each of which is formed on one first electronic component (32P), and the on-third-electrode first conductor circuits (58FW3) each of which is formed on one second electronic component (32N). The multiple on-first-electrode first conductor circuits (58FW1) and the multiple on-third-electrode first conductor circuits (58FW3) are formed. A first electronic component (32P) and a second electronic component (32N), which are adjacent to each other, are connected to each other by one first wiring (58fW). One first electronic component (32P) and one second electronic component (32N) are connected to each other by one first wiring (58fW).

The first via conductors (60F) include the for-fifth-conductor-layer first via conductors (60F5) that connect the first conductor layer (58F) to the fifth conductor layer (34F), the for-first-electrode first via conductors (60F1) that connect the first electrodes (32P1) to the first conductor circuit (58FW), and the for-third-electrode first via conductors (60F3) that connect the third electrodes (32P3) to the first conductor circuit (58FW). The for-fifth-conductor-layer first via conductors (60F5) each have the top diameter (TDF) at the position of the top surface (TF). The for-first-electrode first via conductors (60F1) each have the top diameter (TDF) at the position of the top surface (TF). The for-third-electrode first via conductors (60F3) each have the top diameter (TDF) at the position of the top surface (TF). The top diameter (TDF) of each of the for-fifth-conductor-layer first via conductors (60F5), the top diameter (TDF) of each of the for-first-electrode first via conductors (60F1), and the top diameter (TDF) of each of the for-third-electrode first via conductors (60F3) are substantially equal to each other. The for-first-electrode first via conductors (60F1) and the for-third-electrode first via conductors (60F3) are formed using the alignment mark (TM) as a reference.

One first electrode (32P1) is connected to the first conductor circuit (58FW) by multiple for-first-electrode first via conductors (60F1). For example, the number of the for-first-electrode first via conductors (60F1) connecting one first electrode (32P1) to the first conductor circuit (58FW) is 30 or more and 40 or less.

One third electrode (32P3) is connected to the first conductor circuit (58FW) by multiple for-third-electrode first via conductors (60F3). For example, the number of the for-third-electrode first via conductors (60F3) connecting one third electrode (32P3)) to the first conductor circuit (58FW) is 30 or more and 40 or less.

A plating time is adjusted such that the top part of each of the for-first-electrode first via conductors (60F1) and the for-third-electrode first via conductors (60F3) has a recess. Multiple for-first-electrode first via conductors (60F1) are connected to one conductor circuit. Multiple for-third-electrode first via conductors (60F3) are connected to one conductor circuit. One for-fifth-conductor-layer first via conductor (60F5) is connected to one conductor circuit. Or, multiple for-fifth-conductor-layer first via conductors (60F5) are connected to one conductor circuit. When multiple for-fifth-conductor-layer first via conductors (60F5) and multiple for-first-electrode first via conductors (60F1) are connected to one conductor circuit, the number of the for-fifth-conductor-layer first via conductors (60F5) is smaller than the number of the for-first-electrode first via conductors (60F1). When multiple for-fifth-conductor-layer first via conductors (60F5) and multiple for-third-electrode first via conductors (60F3) are connected to one conductor circuit, the number of the for-fifth-conductor-layer first via conductors (60F5) is smaller than the number of the for-third-electrode first via conductors (60F3). Therefore, when the for-fifth-conductor-layer first via conductors (60F5), the for-first-electrode first via conductors (60F1) and the for-third-electrode first via conductors (60F3) are simultaneously formed, the top part of each of the for-fifth-conductor-layer first via conductors (60F5) is flat, or convex, or recessed. Further, the recess amount (D5) of the top part of each of the for-fifth-conductor-layer first via conductors (60F5) is smaller than the recess amount (D1) of the top part of each of the for-first-electrode first via conductors (60F1). The recess amount (D5) of the top part of each of the for-fifth-conductor-layer first via conductors (60F5) is smaller than the recess amount (D3) of the top part of each of the for-third-electrode first via conductors (60F3).

The second conductor layer (58S) is formed on the second resin insulating layer (50S). At the same time, the second via conductors (60S) penetrating the second resin insulating layer (50S) are formed. The second conductor layer (58S) and the second via conductors (60S) are formed using a semi-additive method. Openings for the second via conductors penetrating the second resin insulating layer (50S) are formed. Then, by filling the openings, the second via conductors (60S) are formed. The openings for the second via conductors each have the top diameter (TDS) at the position of the top surface (TS) of the second resin insulating layer (50S).

The second conductor layer (58S) includes the on-second-electrode second conductor circuits (58SW2) each of which is formed on one first electronic component (32P), and the on-fourth-electrode second conductor circuits (58SW4) each of which is formed on one second electronic component (32N). The multiple on-second-electrode second conductor circuits (58SW2) and the multiple on-fourth-electrode second conductor circuits (58SW4) are formed. A first electronic component (32P) and a second electronic component (32N), which are adjacent to each other, are connected to each other by one second wiring (58sW). One first electronic component (32P) and one second electronic component (32N) are connected to each other by one second wiring (58sW).

The second via conductors (60S) include the for-sixth-conductor-layer second via conductors (60S6) that connect the second conductor layer (58S) to the sixth conductor layer (34S), the for-second-electrode second via conductors (60S2) that connect the second electrodes (32P2) to the second conductor circuit (58SW), and the for-fourth-electrode second via conductors (60S4) that connect the fourth electrodes (32P4) to the second conductor circuit (58SW). The for-sixth-conductor-layer second via conductors (60S6) each have the top diameter (TDS) at the position of the top surface (TS). The for-second-electrode second via conductors (60S2) each have the top diameter (TDS) at the position of the top surface (TS). The for-fourth-electrode second via conductors (60S4) each have the top diameter (TDS) at the position of the top surface (TS). The top diameter (TDS) of each of the for-sixth-conductor-layer second via conductors (60S6), the top diameter (TDS) of each of the for-second-electrode second via conductors (60S2) and the top diameter (TDS) of each of the for-fourth-electrode second via conductors (60S4) are substantially equal to each other.

One second electrode (32P2) is connected to the second conductor circuit (58SW) by multiple for-second-electrode second via conductors (60S2). For example, the number of the for-second-electrode second via conductors (60S2) connecting one second electrode (32P2) to the second conductor circuit (58SW) is 30 or more and 40 or less.

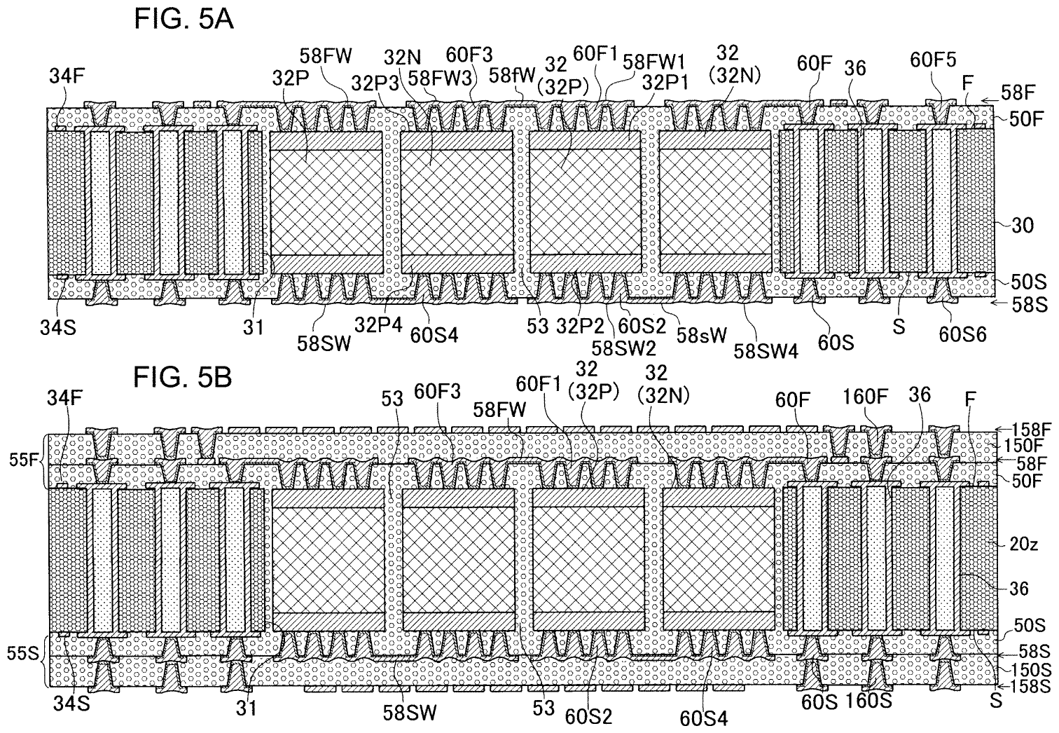

One fourth electrode (32P4) is connected to the second conductor circuit (58SW) by multiple for-fourth-electrode second via conductors (60S4). For example, the number of the for-fourth-electrode second via conductors (60S4) connecting one fourth electrode (32P4) to the second conductor circuit (58SW) is 30 or more and 40 or less (FIG. 5A).

A plating time is adjusted such that the top part of each of the for-second-electrode second via conductors (60S2) and the for-fourth-electrode second via conductors (60S4) has a recess. Multiple for-second-electrode second via conductors (60S2) are connected to one conductor circuit. Multiple for-fourth-electrode second via conductors (60S4) are connected to one conductor circuit. One for-sixth-conductor-layer second via conductor (60S6) is connected to one conductor circuit. Or, multiple for-sixth-conductor-layer sixth-conductor-layer second via conductors (60S6) are connected to one conductor circuit. When multiple for-sixth-conductor-layer second via conductors (60S6) and multiple for-second-electrode second via conductors (60S2) are connected to one conductor circuit, the number of the for-sixth-conductor-layer second via conductors (60S6) is smaller than the number of the for-second-electrode second via conductors (60S2). When multiple for-sixth-conductor-layer second via conductors (60S6) and multiple for-fourth-electrode second via conductors (60S4) are connected to one conductor circuit, the number of the for-sixth-conductor-layer second via conductors (60S6) is smaller than the number of the for-fourth-electrode second via conductors (60S4). Therefore, when the for-sixth-conductor-layer second via conductors (60S6), the for-second-electrode second via conductors (60S2) and the for-fourth-electrode second via conductors (60S4) are simultaneously formed, the top part of each of the for-sixth-conductor-layer second via conductors (60S6) is flat, or convex, or recessed. Further, the recess amount (D6) of the top part of each of the for-sixth-conductor-layer second via conductors (60S6) is smaller than the recess amount (D2) of the top part of each of the for-second-electrode second via conductors (60S2). The recess amount (D6) of the top part of each of the for-sixth-conductor-layer second via conductors (60S6) is smaller than the recess amount (D4) of the top part of each of the for-fourth-electrode second via conductors (60S4).

The third resin insulating layer (150F) is formed on the first conductor layer (58F) and the first resin insulating layer (50F). The third conductor layer (158F) is formed on the third resin insulating layer (150F) using a semi-additive method. The third resin insulating layer (150F) covers the top parts of the first via conductors. The recesses formed in the top parts of the for-first-electrode first via conductors (60F1) and the recesses formed in the top parts of the for-third-electrode first via conductors (60F3) are filled with the third resin insulating layer (150F). The third via conductors (160F) penetrating the third resin insulating layer (150F) and connecting the first conductor layer (58F) and the third conductor layer (158F) to each other are formed (FIG. 5B). For example, there is no third via conductor (160F) that connects the third conductor layer (158F) and the first conductor circuit (58FW) to each other.

The fourth resin insulating layer (150S) is formed on the second conductor layer (58S) and the second resin insulating layer (50S). The fourth conductor layer (158S) is formed on the fourth resin insulating layer (150S) using a semi-additive method. The fourth resin insulating layer (150S) covers the top parts of the second via conductors. The recesses formed in the top parts of the for-second-electrode second via conductors (60S2) and the recesses formed in the top parts of the for-fourth-electrode second via conductors (60S4) are filled with the fourth resin insulating layer (150S). The fourth via conductors (160S) penetrating the fourth resin insulating layer (150S) and connecting the second conductor layer (58S) and the fourth conductor layer (158S) to each other are formed (FIG. 5B). For example, there is no fourth via conductors (160S) that connects the fourth conductor layer (158S) and the second conductor circuit (58SW) to each other.

The first solder resist layer (70F) having the first openings (71F) are formed on the third conductor layer (158F) and the third resin insulating layer (150F). The second solder resist layer (70S) having second openings (71S) are formed on the fourth conductor layer (158S) and the fourth resin insulating layer (150S). The printed wiring board 10 is completed (FIG. 1A). The third conductor layer (158F) exposed from the first openings (71F) functions as the pads for mounting an electronic component. The fourth conductor layer (158S) exposed from the second openings (71S) functions as the pads for connecting to a motherboard.

### Second Embodiment

FIG. 6A is a cross-sectional view of a printed wiring board 110 of a second embodiment. In the printed wiring board 110, three kinds of electronic components 33 are accommodated in the opening 31 of the core substrate 30. Examples of the electronic components 33 accommodated in the one opening 31 are capacitors (33C), inductors (33L) and resistors (33R).

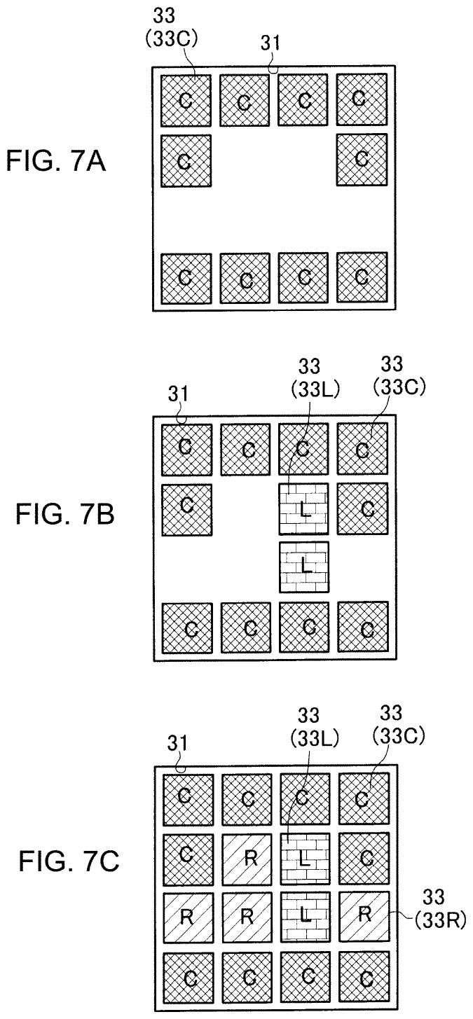

Manufacturing Method of Second Embodiment FIGS. 7A-7C illustrate a part of a method for manufacturing the printed wiring board 110 of the second embodiment. FIGS. 7A-7C illustrate a method for mounting the electronic component 33 on the tape 18 which closes the opening 31.

Similar to the first embodiment, using the alignment mark (TM) as a reference, first, first electronic components such as the capacitors (33C) are mounted one by one on the tape 18 in the opening 31. The accommodation of the first electronic components such as the capacitors (33C) is completed. As illustrated in FIG. 7A, all the first electronic components such as the capacitors (33C) are mounted on the tape 18 exposed from the opening 31. After that, using the alignment mark (TM) as a reference, second electronic components such as the inductors (33L) are mounted one by one on the tape 18. The accommodation of the second electronic components such as the inductors (33L) is completed. All the second electronic components such as the inductors (33L) are mounted on the tape 18 exposed from the opening 31 (FIG. 7B). Finally, using the alignment mark (TM) as a reference, third electronic components such as the resistors (33R) are mounted one by one on the tape 18 (FIG. 7C). The accommodation of the third electronic components such as the resistors (33R) is completed. All the third electronic components such as the resistors (33R) are mounted on the tape 18 exposed from the opening 31. The three kinds of electronic components 33 are arranged at intersection points of rows and columns.

A method for forming the core substrate 30 of the first embodiment and a method for forming the core substrate 30 of the second embodiment are the same. A method for forming the first build-up layer (55F) of the first embodiment and a method for forming the first build-up layer (55F) of the second embodiment are the same. A method for forming the second build-up layer (55S) of the first embodiment and a method for forming the second build-up layer (55S) of the second embodiment are the same. A method for forming the first solder resist layer (70F) of the first embodiment and a method for forming the first solder resist layer (70F) of the second embodiment are the same. A method for forming the second solder resist layer (70S) of the first embodiment and a method for forming the second solder resist layer (70S) of the second embodiment are the same.

In the printed wiring board of the second embodiment, the top part of each of the via conductors connected to the electronic components embedded in the core substrate is recessed. And, the recesses are filled with the resin insulating layer.

In each of the embodiments, a row is substantially parallel to the side wall of the core substrate exposed from the opening 31 for accommodating the electronic components 33. A column is substantially parallel to the side wall of the core substrate exposed from the opening 31 for accommodating the electronic components 32.

The first conductor circuit (58FW) can include a first conductor circuit (58FWF1) that connects the first electronic components (32P) to the through-hole conductors (36S) (the through-hole conductors among the for-built-in-component wirings) in FIG. 1A, and a first conductor circuit (58FWF2) that connect the second electronic components (32N) to the through-hole conductors (36S) (the through-hole conductors among the for-built-in-component wirings) in FIG. 1A.

The second conductor circuit (58SW) can include a second conductor circuit that connects the first electronic components (32P) to the through-hole conductors among the for-built-in-component wirings, and a second conductor circuit that connects the second electronic components (32N) to the through-hole conductors (36S) among the for-built-in-component wirings.

FIG. 6C illustrates two first electronic components (32P) (32PI, 32PII) and two second electronic components (32N) (32NI, 32NII) arranged in one row. As illustrated in FIG. 6C, the electronic components are arranged in an order of the first electronic component (32PI), the second electronic component (32NI), the first electronic component (32PII), and the second electronic component (32NII). A straight line (L2) connecting a centroid of the first surface (F1) of the first electronic component (32PI) and a centroid of the first surface (F1) of the first electronic component (32PII) is illustrated in FIG. 6C. A straight line (L1) connecting a centroid of the third surface (F2) of the second electronic component (32NI) and a centroid of the third surface (F2) of the second electronic component (32NII) is illustrated in FIG. 6C. The straight line (L1) and the straight line (L2) do not overlap each other. There is a gap between the straight line (L1) and the straight line (L2). Heat conduction can be increased.

A straight line connecting a centroid of the first surface of one first electronic component arranged on a specific row and a centroid of the first surface of another first electronic component arranged on the specific row and a straight line connecting a centroid of the third surface of one second electronic component arranged on the specific row and a centroid of the third surface of another second electronic component arranged on the specific row do not overlap each other.

FIG. 6D illustrates two first electronic components (32P) (32PI, 32PII) and two second electronic components (32N) (32NI, 32NII) arranged in one column. As illustrated in FIG. 6D, the electronic components are arranged in an order of the first electronic component (32PI), the second electronic component (32NI), the first electronic component (32PII), and the second electronic component (32NII). A straight line (L4) connecting a centroid of the first surface (F1) of the first electronic component (32PI) and a centroid of the first surface (F1) of the first electronic component (32PII) is illustrated in FIG. 6D. A straight line (L3) connecting a centroid of the third surface (F2) of the second electronic component (32NI) and a centroid of the third surface (F2) of the second electronic component (32NII) is illustrated in FIG. 6D. The straight line (L3) and the straight line (L4) do not overlap each other. There is a gap between the straight line (L3) and the straight line (L4). Heat conduction can be increased.

A straight line connecting a centroid of the first surface of one first electronic component arranged on a specific column and a centroid of the first surface of another first electronic component arranged on the specific column and a straight line connecting a centroid of the third surface of one second electronic component arranged on the specific column and a centroid of the third surface of another second electronic component arranged on the specific column do not overlap each other.

According to an embodiment, temperature of an electronic component mounted on the printed wiring board can be controlled within a predetermined range.

In Japanese Patent Laid-Open Publication No. 2012-39050, through holes are formed in the metal substrate. And, in Japanese Patent Laid-Open Publication No. 2012-39050, one semiconductor element is accommodated in each of the through holes. Therefore, according to Japanese Patent Laid-Open Publication No. 2012-39050, it is expected that, when the number of the semiconductor elements embedded in the metal substrate increases, the substrate becomes large.

A printed wiring board according to an embodiment of the present invention includes: a core substrate having a core material that has a fifth surface and a sixth surface on an opposite side with respect to the fifth surface, and having an opening that penetrates the core material and is for accommodating multiple first electronic components and multiple second electronic components; the multiple first electronic components accommodated in the opening; the multiple second electronic components accommodated in the opening; a first build-up layer formed on the fifth surface and on the opening; and a second build-up layer formed on the sixth surface and on the opening. The first electronic components are each formed of a first main body having a first surface and a second surface on an opposite side of the first surface, a first electrode on the first surface, and a second electrode on the second surface, and the first electronic components are each accommodated in the core substrate such that the first surface and the fifth surface oppose each other. The second electronic components are each formed of a second main body having a third surface and a fourth surface on an opposite side with respect to the third surface, a third electrode on the third surface, and a fourth electrode on the fourth surface, and the second electronic components are each accommodated in the core substrate such that the third surface and the fifth surface oppose each other. The first build-up layer includes: a first resin insulating layer covering the opening; a first conductor layer formed on the first resin insulating layer; first via conductors penetrating the first resin insulating layer and connecting to the first conductor layer; and a third resin insulating layer formed on the first resin insulating layer, the first conductor layer and the first via conductors. The first conductor layer has a first conductor circuit formed directly over the opening, and an on-core-material first conductor circuit formed directly over the core material. The first via conductors include for-fifth-conductor-layer first via conductors that connect the first conductor layer to the fifth conductor layer, for-first-electrode first via conductors that connect the first electrodes to the first conductor circuit, and for-third-electrode first via conductors that connect the third electrodes to the first conductor circuit. A top part of each of the for-first-electrode first via conductors and the for-third-electrode first via conductors is recessed. A top part of each of the for-fifth-conductor-layer first via conductors is flat, or convex, or recessed, and, when the top part of each of the for-fifth-conductor-layer first via conductors has a recess, a size of the recess of the top part of each of the for-first-electrode first via conductors and a size of the recess of the top part of each of the for-third-electrode first via conductors are larger than a size of the recess of the top part of each of the for-fifth-conductor-layer first via conductors.

According an embodiment of the present invention, the multiple first electronic components and the multiple second electronic components are accommodated in the one opening formed in the core substrate. Therefore, it is possible that the core substrate is not formed between the first electronic components and the second electronic components. Even when two or more kinds of electronic components are accommodated in the printed wiring board, the printed wiring board can be reduced in size.

In a printed wiring board according to an embodiment of the present invention, the top part of each of the via conductors connected to the electrodes of the electronic components embedded in the core substrate has a recess. And, the resin insulating layer is formed on these via conductors. The resin insulating layer is formed on the via conductors via the recesses of the top parts of the via conductors. Therefore, a contact area between the via conductors connected to the electronic components in the opening and the resin insulating layer is increased. Even when multiple kinds of electronic components are embedded in the opening, peeling is unlikely to occur at an interface between the via conductors connected to the electronic components in the opening and the resin insulating layer. Further, when the contact area between the via conductors connected to the electronic components in the opening and the resin insulating layer is increased, heat is easily transmitted to the via conductors connected to the electronic components in the opening via the resin insulating layer. Then, the heat is transmitted to the electronic components in the opening via the via conductors connected to the electronic components in the opening. Heat conduction can be increased.

Obviously, numerous modifications and variations of the present invention are possible in light of the above teachings. It is therefore to be understood that within the scope of the appended claims, the invention may be practiced otherwise than as specifically described herein.

What is claimed is:

1. A printed wiring board, comprising:
a core substrate comprising a core material and having an opening such that the opening is penetrating through the core material;
a plurality of first electronic components accommodated in the opening of the core substrate and each comprising a first main body, a first electrode on one side of the first main body, and a second electrode on an opposite side of the first main body;
a plurality of second electronic components accommodated in the opening of the core substrate and each comprising a second main body, a third electrode on one side of the second main body, and a fourth electrode on an opposite side of the second main body;
a first build-up layer formed on a surface of the core substrate and comprising a first resin insulating layer covering the opening of the core substrate, a first conductor layer formed on the first resin insulating layer, a plurality of first via conductors penetrating through the first resin insulating layer and connecting to the first conductor layer, and a third resin insulating layer formed on the first resin insulating layer such that the third resin insulating layer is formed over the first conductor layer and the first via conductors,
wherein the first build-up layer is formed such that the first conductor layer includes a first conductor circuit formed directly over the opening of the core substrate, and an on-core-material first conductor circuit formed directly over the core material, that the first via conductors include a group of the first via conductors that connects the first conductor layer to a conductor layer formed on the surface of the core substrate, a group of the first via conductors that connects the first electrodes of the first electronic components to the first conductor circuit, and a group of the first via conductors that connects the third electrodes of the second electronic components to the first conductor circuit, and that each of the first via conductors in the groups connected to the first and third electrodes has a recessed top portion.

2. The printed wiring board according to claim 1, wherein the plurality of first via conductors is formed such that each of the first via conductors in the group connected to the conductor layer formed on the surface of the core substrate has a recessed top portion and that the recessed top portion of each of the first via conductors in the groups connected to the first and third electrodes has a size that is larger than a size of the recessed top portion of each of the first via conductors in the group connected to the conductor layer formed on the surface of the core substrate.

3. The printed wiring board according to claim 1, wherein each of the first electronic component is a P-type thermoelectric element, and each of the second electronic component is an N-type thermoelectric element.

4. The printed wiring board according to claim 1, wherein the first electronic components and the second electronic components are positioned at intersection points of rows and columns and are alternately positioned.

5. The printed wiring board according to claim 1, wherein the plurality of first via conductors is formed such that the first via conductors have substantially equal top diameters at a surface of the first resin insulating layer on which the first conductor layer is formed.

6. The printed wiring board according to claim 1, wherein each of the first electrodes is connected to the first conductor circuit of the first conductor layer by at least two of the first via conductors, and each of the third electrodes is connected to the first conductor circuit of the first conductor layer by at least two of the first via conductors.

7. The printed wiring board according to claim 6, wherein the plurality of first via conductors is formed such that a number of the at least two of the first via conductors connected to the first electrodes is in a range of 30 to 40, and that a number of the at least two of the first via conductors connected to the third electrodes is in a range of 30 to 40.

8. The printed wiring board according to claim 1, wherein the core substrate is formed such that spaces formed between the first electronic components and the second electronic components in the opening of the core substrate are filled with a resin from the first resin insulating layer.

9. The printed wiring board according to claim 4, wherein a number of the rows is equal to a number of the columns.

10. The printed wiring board according to claim 4, wherein a number of the rows is 4 or more, and a number of the columns is 4 or more.

11. The printed wiring board according to claim 2, wherein each of the first electronic component is a P-type thermoelectric element, and each of the second electronic component is an N-type thermoelectric element.

12. The printed wiring board according to claim 2, wherein the first electronic components and the second electronic components are positioned at intersection points of rows and columns and are alternately positioned.

13. The printed wiring board according to claim 2, wherein the plurality of first via conductors is formed such that the first via conductors have substantially equal top diameters at a surface of the first resin insulating layer on which the first conductor layer is formed.

14. The printed wiring board according to claim 2, wherein each of the first electrodes is connected to the first conductor circuit of the first conductor layer by at least two of the first via conductors, and each of the third electrodes is connected to the first conductor circuit of the first conductor layer by at least two of the first via conductors.

15. The printed wiring board according to claim 14, wherein the plurality of first via conductors is formed such that a number of the at least two of the first via conductors connected to the first electrodes is in a range of 30 to 40, and that a number of the at least two of the first via conductors connected to the third electrodes is in a range of 30 to 40.

16. The printed wiring board according to claim 2, wherein the core substrate is formed such that spaces formed between the first electronic components and the second electronic components in the opening of the core substrate are filled with a resin from the first resin insulating layer.

17. The printed wiring board according to claim 12, wherein a number of the rows is equal to a number of the columns.

18. The printed wiring board according to claim 12, wherein a number of the rows is 4 or more, and a number of the columns is 4 or more.

19. The printed wiring board according to claim 1, wherein the plurality of first via conductors is formed such that each of the first via conductors in the group connected to the conductor layer formed on the surface of the core substrate has a convex top portion.

20. The printed wiring board according to claim 1, wherein the plurality of first via conductors is formed such that each of the first via conductors in the group connected to the conductor layer formed on the surface of the core substrate has a flat top portion.
